(19) United States
(12) Patent Application Publication
(10) Pub. No.: US 2026/0181914 A1
(43) Pub. Date: Jun. 25, 2026

(54) SEMICONDUCTOR DEVICE AND DATA STORAGE SYSTEM INCLUDING SEMICONDUCTOR DEVICE

(71) Applicant: Samsung Electronics Co., Ltd., Suwon-si (KR)

(72) Inventors: Junghoon PARK, Suwon-si (KR); Juhyung KIM, Suwon-si (KR)

(73) Assignee: Samsung Electronics Co., Ltd., Suwon-si (KR)

(21) Appl. No.: 19/237,682

(22) Filed: Jun. 13, 2025

(30) Foreign Application Priority Data
Dec. 20, 2024 (KR) 10-2024-0192843

(51) Int. Cl. H10B 63/00; H10B 80/00; H10N 70/00

(52) U.S. Cl. CPC H10B 63/845; H10B 63/30; H10B 80/00; H10N 70/8836

(57) ABSTRACT

A semiconductor device includes a substrate, a stack structure including gate electrodes spaced apart from each other in a vertical direction, and a channel structure extending vertically in a channel hole through the stack structure in the vertical direction. The channel structure includes a channel layer on a sidewall of the channel hole, a resistance switching layer between the sidewall of the channel hole and the channel layer, the resistance switching layer configured to vary an electrical conductivity based on an electrochemical reaction involving a loss or a gain of oxygen ions, a diffusion barrier structure between the sidewall of the channel hole and the resistance switching layer, an electrolyte layer between the channel hole and the diffusion barrier structure, and an ion storage layer between the channel hole and the electrolyte layer. The diffusion barrier structure includes at least two diffusion barrier layers sequentially stacked.

### CROSS-REFERENCE TO RELATED APPLICATION(S)

This application claims benefit of priority to Korean Patent Application No. 10-2024-0192843 filed on Dec. 20, 2024 in the Korean Intellectual Property Office, the disclosure of which is incorporated herein by reference in its entirety.

### BACKGROUND

Example embodiments of the present inventive concepts relate to a semiconductor device and a data storage system including the same.

In electronic systems utilizing data storage, semiconductor devices capable of storing higher-capacity data is increasingly in demand. Accordingly, methods of increasing data storage capacity of semiconductor devices have been researched. For example, a method of increasing data storage capacity of semiconductor devices may include manufacturing semiconductor devices including memory cells arranged three-dimensionally, instead of memory cells arranged two-dimensionally.

### SUMMARY

Some example embodiments the present inventive concepts provide a semiconductor device having improved reliability.

Some example embodiments of the present inventive concepts provide a data storage system including a semiconductor device having improved reliability, the semiconductor device capable of low-voltage operations.

According to some example embodiments of the present inventive concepts, there is provided a semiconductor device including a substrate, a stack structure including gate electrodes spaced apart from each other in a vertical direction, the vertical direction being perpendicular to an upper surface of the substrate, and a channel structure extending vertically in a channel hole through the stack structure in the vertical direction. The channel structure includes a channel layer on a sidewall of the channel hole, a resistance switching layer between the sidewall of the channel hole and the channel layer, the resistance switching layer configured to vary an electrical conductivity based on an electrochemical reaction involving a loss or a gain of oxygen ions, a diffusion barrier structure between the sidewall of the channel hole and the resistance switching layer, an electrolyte layer between the sidewall of the channel hole and the diffusion barrier structure, and an ion storage layer between the sidewall of the channel hole and the electrolyte layer. The diffusion barrier structure includes at least two diffusion barrier layers sequentially stacked in a direction from the resistance switching layer toward the electrolyte layer.

According to some example embodiments of the present inventive concepts, there is provided a semiconductor device including a substrate, a stack structure including gate electrodes spaced apart from each other in a vertical direction, the vertical direction being perpendicular to an upper surface of the substrate; and a channel structure extending vertically in a channel hole through the stack structure in the vertical direction. The channel structure includes a circular insulating pillar in a center of the channel hole, an ion-providing structure surrounding an external surface of the circular insulating pillar, the ion-providing structure including a first metal oxide, and the ion-providing structure configured to vary an electrical conductivity based on an electrochemical reaction involving a loss or a gain of oxygen ions, a diffusion barrier structure surrounding an external surface of the ion-providing structure, the diffusion barrier structure including a second metal oxide, an electrolyte layer surrounding an external surface of the diffusion barrier structure, the electrolyte layer including a third metal oxide, and an ion storage layer surrounding an external surface of the electrolyte layer, the ion storage layer including a fourth metal oxide. The diffusion barrier structure includes at least two diffusion barrier layers sequentially stacked between the ion-providing structure and the electrolyte layer, the diffusion barrier structure configured to reduce re-diffusion of the oxygen ions from the ion storage layer.

According to some example embodiments of the present inventive concepts, there is provided a data storage system including a semiconductor storage device including a channel structure in a channel hole extending through gate electrodes stacked on a substrate, and a controller electrically connected to the semiconductor storage device, the controller configured to control the semiconductor storage device. The channel structure includes a circular insulating pillar in a center of the channel hole, an ion-providing structure surrounding an external surface of the circular insulating pillar, the ion-providing structure including a first metal oxide, and configured to vary an electrical conductivity based on an electrochemical reaction involving a loss or a gain of oxygen ions, a diffusion barrier structure surrounding an external surface of the ion-providing structure, the diffusion barrier structure including a second metal oxide, an electrolyte layer surrounding an external surface of the diffusion barrier structure, the electrolyte layer including a third metal oxide, and an ion storage layer surrounding an external surface of the electrolyte layer, the ion storage layer including a fourth metal oxide. The diffusion barrier structure includes at least two diffusion barrier layers sequentially stacked between the ion-providing structure and the electrolyte layer, the diffusion barrier structure configured to reduce re-diffusion of the oxygen ions from the ion storage layer.

According to some example embodiments of the present inventive concepts, there is provided a method of manufacturing a semiconductor device including forming a mold structure by alternately stacking interlayer insulating layers and sacrificial insulating layers on a semiconductor substrate, forming channel holes passing through the mold structure, forming an ion storage layer, and an electrolyte layer in the channel holes; and forming a diffusion barrier structure by sequentially stacking a plurality of diffusion barrier layers on the electrolyte layer.

According to some example embodiments of the present inventive concepts, in the method of manufacturing the semiconductor device, in the forming the diffusion barrier structure, each of the plurality of diffusion barrier layers includes a metal oxide, and each of the plurality of diffusion barrier layers includes a different concentration of oxygen.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1A is a schematic plan view of a semiconductor device according to some example embodiments;

FIG. 1B is a partially enlarged view of the semiconductor device of FIG. 1A;

FIG. 2 is a schematic cross-sectional view of a semiconductor device according to some example embodiments;

FIG. 3A is a partially enlarged view of a semiconductor device according to some example embodiments;

FIG. 3B is a graph illustrating characteristics of diffusion barrier layers of the semiconductor device of FIG. 3A;

FIG. 4 is a graph illustrating characteristics according to a thickness of a metal oxide;

FIGS. 5A to 5C illustrate the movement of ions and current flow in a program operation, a read operation, and an erase operation of the semiconductor device of FIG. 3A;

FIGS. 6A to 17 are partially enlarged views of semiconductor devices according to some example embodiments and graphs illustrating characteristics of diffusion barrier layers of the semiconductor devices according to each of some example embodiments;

FIG. 18 is a flowchart illustrating a method of manufacturing the semiconductor device of FIG. 2;

FIG. 19 is a schematic diagram illustrating a data storage system including a semiconductor device according to some example embodiments; and

FIG. 20 is a schematic perspective view of a data storage system including a semiconductor device according to some example embodiments.

### DETAILED DESCRIPTION

Hereinafter, some example embodiments of the present disclosure will be described with reference to the accompanying drawings. Hereinafter, terms such as “top,” “upper portion,” “upper surface,” “above,” “bottom,” “lower portion,” “lower surface,” “below,” and “side surface” can be understood as being referred to, based on the drawings, except for when denoted by reference numerals.

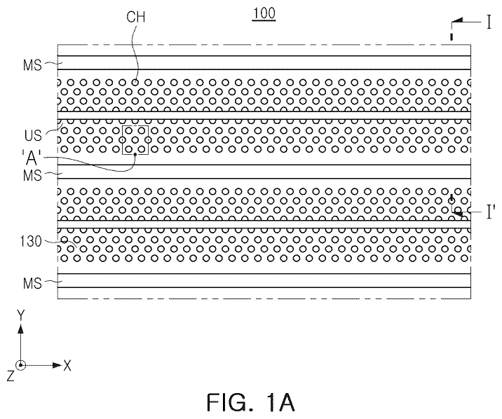

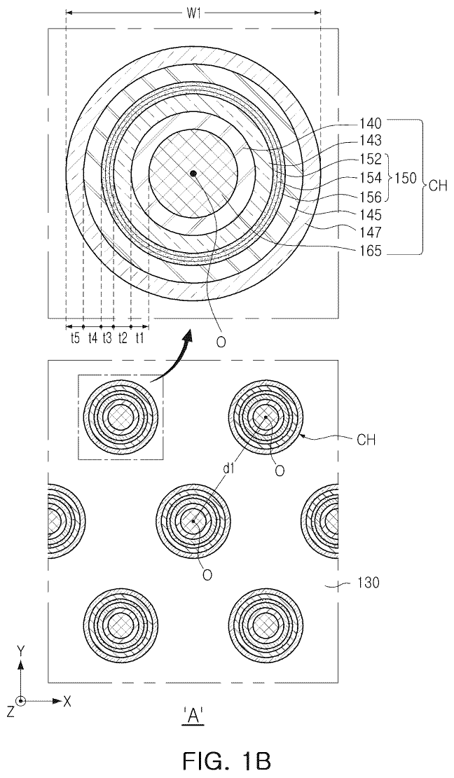

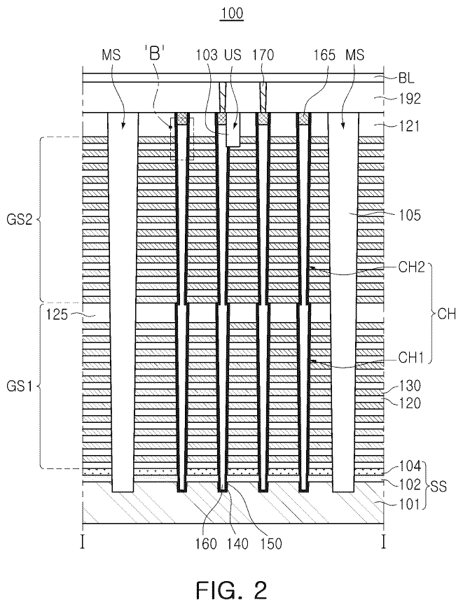

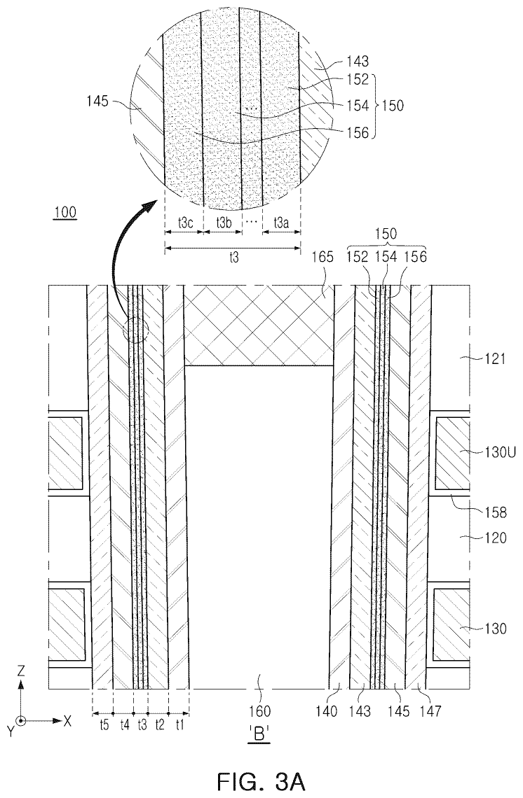

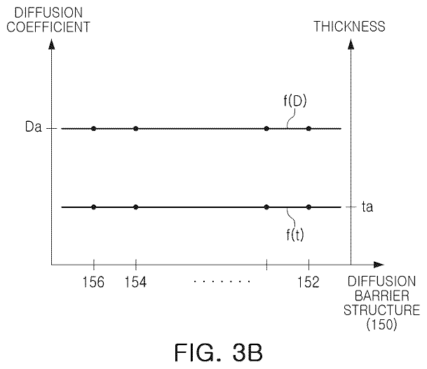

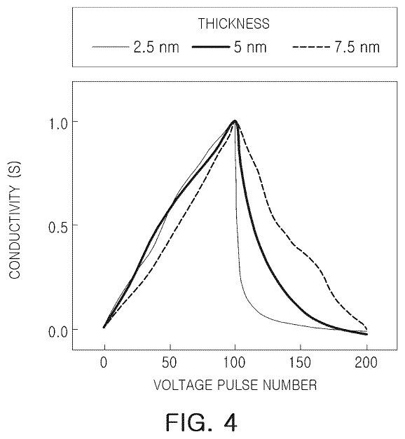

FIG. 1A is a schematic plan view of a semiconductor device according to some example embodiments. FIG. 1B is a partially enlarged view of portion “A” of the semiconductor device of FIG. 1A. FIG. 2 is a schematic cross-sectional view of a semiconductor device according to some example embodiments, taken along line I-I'. FIG. 3A is an enlarged view of portion “B” of a semiconductor device according to some example embodiments. FIG. 3B is a graph illustrating characteristics of the semiconductor device of FIG. 3A. FIG. 4 is a graph illustrating a degree of ion diffusion according to thicknesses of diffusion barrier layers.

Referring to FIGS. 1A to 4, a semiconductor device 100 may include a semiconductor substrate 101, a source structure SS including first and second horizontal conductive layers 102 and 104 on the semiconductor substrate 101, gate electrodes 130 stacked on the semiconductor substrate 101, interlayer insulating layers 120 stacked on the semiconductor substrate 101 alternately with the gate electrodes 130, channel structures CH disposed to pass through first and second stack structures GS1 and GS2 of the gate electrodes 130, the channel structures CH including a channel layer 140, upper isolation regions US passing through a portion of the second stack structure GS2, isolation regions MS extending through the first and second stack structures GS1 and GS2, contact plugs 170 on the channel structures CH, gate electrodes 130, and a cell region insulating layer 192 covering the channel structures CH.

In the semiconductor device 100, a single memory cell string may be configured with respect to each channel structure CH, and a plurality of memory cell strings may be arranged in columns and rows in an X-direction and a Y-direction.

The semiconductor substrate 101 may have an upper surface extending in the X-direction and the Y-direction. The semiconductor substrate 101 may include a semiconductor material, for example, a group IV semiconductor, a group III-V compound semiconductor, or a group II-VI compound semiconductor. For example, the group IV semiconductor may include silicon, germanium, or silicon-germanium. The semiconductor substrate 101 may be provided as a bulk wafer, an epitaxial layer, a silicon on insulator (SOI) layer, or a semiconductor on insulator (SeOI) layer. However, example embodiments are not limited thereto.

The first and second horizontal conductive layers 102 and 104 may be stacked and disposed on the upper surface of the semiconductor substrate 101. The first and second horizontal conductive layers 102 and 104, source layers, may form a source structure SS together with the semiconductor substrate 101. The source structure SS may function as a common source line of the semiconductor device 100. The first horizontal conductive layer 102 may be directly connected to the channel layer 140 at a periphery of the channel layer 140. The first horizontal conductive layer 102 may partially extend in a Z-direction along the channel layer 140 to be in contact with the channel layer 140.

The first and second horizontal conductive layers 102 and 104 may include a semiconductor material, and may include, for example, polycrystalline silicon. However, example embodiments are not limited thereto. In this case, at least the first horizontal conductive layer 102 may be a layer doped with impurities having a conductance type the same as that of the semiconductor substrate 101, and the second horizontal conductive layer 104 may be a doped layer or an intrinsic semiconductor layer including impurities diffused from the first horizontal conductive layer 102. However, a material of the second horizontal conductive layer 104 is not limited to a semiconductor material, and may be replaced with an insulating layer in some example embodiments. In some example embodiments, an insulating layer having a relatively small thickness may be interposed between an upper surface of the first horizontal conductive layer 102 and a lower surface of the second horizontal conductive layer 104.

The gate electrodes 130 may be vertically spaced apart and stacked on the semiconductor substrate 101 to form first and second stack structures GS1 and GS2. The gate electrodes 130 may include a lower gate electrode forming a gate of a ground selection transistor, memory gate electrodes forming a plurality of memory cells, and upper gate electrodes 130U forming gates of string selection transistors. The number of the memory gate electrodes, forming the memory cells, may be determined depending on a capacity of the semiconductor device 100. In some example embodiments, each of the number of the upper gate electrodes and the number of the lower gate electrodes may be one or two or more, and may have a structure the same as or different from that of the memory gate electrodes. In some example embodiments, the gate electrodes 130 may further include a gate electrode 130 disposed above the upper gate electrodes 130U and/or below the lower gate electrode, the gate electrode 130 forming an erase transistor used for an erase operation using a gate induced drain leakage current (GIDL) phenomenon. In addition, some gate electrodes 130, for example, gate electrodes adjacent to the upper or lower gate electrodes, may be dummy gate electrodes.

The gate electrodes 130 may include a metal material, for example, tungsten (W). However, example embodiments are not limited thereto. In some example embodiments, the gate electrodes 130 may include polycrystalline silicon or a metal silicide material. In some example embodiments, the gate electrodes 130 may further include a diffusion barrier 158. For example, the diffusion barrier 158 may include tungsten nitride (WN), tantalum nitride (TaN), titanium nitride (TiN), or combinations thereof. However, example embodiments are not limited thereto.

The interlayer insulating layers 120 may be disposed between the gate electrodes 130. In the same manner as the gate electrodes 130, the interlayer insulating layers 120 may also be disposed to be spaced apart from each other in a direction, perpendicular to the upper surface of the semiconductor substrate 101. The interlayer insulating layers 120 may include an insulating material such as silicon oxide or silicon nitride. However, example embodiments are not limited thereto.

Among the interlayer insulating layers 120, an intermediate insulating layer 125 and an uppermost interlayer insulating layer 121 between the stack structures GS1 and GS2 may have thicknesses greater than those of other interlayer insulating layers 120, but the example embodiments are not limited thereto.

The channel structures CH may respectively form a single memory cell string, and may be disposed on the semiconductor substrate 101 in rows and columns to be spaced apart from each other. The channel structures CH may be disposed to form a lattice pattern or to have a zigzag shape in one direction, on an X-Y plane. The channel structures CH may have a pillar shape filling a channel hole, and may have inclined side surfaces becoming narrower as a distance from the semiconductor substrate 101 decreases depending on aspect ratio. As illustrated in FIG. 3A, each of the channel structures CH may include, in addition to the channel layer 140, a resistance switching layer 143 on an external surface of the channel layer 140, a diffusion barrier structure 150, an electrolyte layer 145, and an ion storage layer 147, and may further include a buried insulating layer 160 inside of the channel layer 140, and a channel pad 165 on an upper end of the channel structure CH.

A multilayer material layer, forming the channel structures CH, may have a structure in which oxygen ions are diffusible, and may include metal oxides, preferably transition metal oxides.

The buried insulating layer 160 may be disposed as an insulating pillar in a center O of the channel hole. The buried insulating layer 160 may have a circular cross-section in the X-Y plane, and may be formed of an insulating material such as silicon oxide, silicon nitride, or the like. However, example embodiments are not limited thereto.

The channel layer 140 may have an annular shape surrounding the buried insulating layer 160 therein. However, in some example embodiments, the buried insulating layer 160 may be omitted, and the channel layer 140 may have a pillar shape such as a cylinder filling the channel hole. The channel layer 140 may include a metal oxide semiconductor or a silicon semiconductor. For example, the channel layer 140 may include one of WOₓ, IGZO, IZO, ZnO, ZTO, InO, PCMO, TiO₂, or one of poly-Si and c-Si. However, example embodiments are not limited thereto.

The channel layer 140 may be a layer, not doped with conductive impurities such as P-type or N-type impurities during a manufacturing process. That is, the channel layer 140 may be a layer, not intentionally doped with conductive impurities. However, in some example embodiments, the channel layer 140 may further include N-type impurities diffused from an upper region and/or a lower region and the source structure SS. For example, when the gate electrodes 130 include an erase gate electrode forming the erase transistor, N-type impurities may be further included in a region parallel to the erase gate electrode. The channel layer 140 may have a first thickness t1, and may have a substantially uniform thickness from an upper portion thereof to a lower portion thereof.

The resistance switching layer 143 may be disposed between the gate electrodes 130 and the channel layer 140. The resistance switching layer 143 may be disposed to cover an external surface and a bottom surface of the channel layer 140, and may have an annular shape surrounding the external surface of the channel layer 140, in a plan view. The resistance switching layer 143 may include a metal oxide, and may include a transition metal oxide such as WO_{z} or the like. However, example embodiments are not limited thereto. The resistance switching layer 143 may include a material exhibiting a significant change in electrical conductivity due to an electrochemical reaction caused by the loss of oxygen ions in the metal oxide, and a resistance value may be changed due to a change in electrical conductivity caused by the loss of oxygen ions or by the gain of the oxygen ions, thereby allowing current to flow together with the channel layer 140.

The resistance switching layer 143 includes a material having a higher ion diffusion coefficient to facilitate the loss and gain of oxygen ions, and a second thickness t2 of the resistance switching layer 143 may be substantially the same as the first thickness t1 of the channel layer 140.

The diffusion barrier structure 150 may be disposed along an external surface of the resistance switching layer 143. In a plan view, the diffusion barrier structure 150 may form an annular shape surrounding the external surface of the resistance switching layer 143. The diffusion barrier structure 150 may include a metal oxide, and preferably, as a transition metal oxide, may include at least one of WOₓ, HfO_{y}, AlOₓ. However, example embodiments are not limited thereto. The diffusion barrier structure 150 may have an overall third thickness t3, and the third thickness t3 may be less than the first thickness t1 of the channel layer 140, but may be greater than ½ of the first thickness t1. For example, the third thickness t3 may satisfy 0.6 to 0.8 times the first thickness t1, but the example embodiments are not limited thereto.

The diffusion barrier structure 150 may have an overall ion diffusion coefficient significantly lower than that of the resistance switching layer 143 and the ion storage layer 147, and may reduce and/or prevent oxygen ions stored in the ion storage layer 147 from being re-diffused into the resistance switching layer 143, thereby improving data retention efficiency. In addition, the diffusion barrier structure 150 may include a material having a degree of ionization lower than that of the electrolyte layer 145. In this case, the degree of ionization may be defined not as the ease of ion formation in a solution but as the ease of ion formation when a voltage is applied.

A plurality of diffusion barrier layers 156, 154, . . . , and 152 may be sequentially disposed as the diffusion barrier structure 150. The term “sequentially disposed” may be understood as being disposed from an upper end to a lower end of the channel hole while covering external surfaces and bottom surfaces of previous diffusion barrier layers 156, 154, . . . , and 152. The plurality of diffusion barrier layers 156, 154, . . . , and 152 in the diffusion barrier structure 150 may include at least a three-layer stack structure, and the diffusion barrier layers 156, 154, . . . , and 152 may include the same material, but the present inventive concepts are not limited thereto.

The plurality of diffusion barrier layers 156, 154, . . . , and 152 may include tungsten oxide. However, example embodiments are not limited thereto. When the resistance switching layer 143 also includes tungsten oxide, the plurality of diffusion barrier layers 156, 154, . . . , and 152 may have an oxygen concentration higher than an oxygen concentration of the resistance switching layer 143.

The plurality of diffusion barrier layers 156, 154, . . . , and 152 may all include HfO_{y}. However, example embodiments are not limited thereto. The plurality of diffusion barrier layers 156, 154, . . . , and 152 may suppress the movement of oxygen ions at interfaces between the diffusion barrier layers 156, 154, . . . , and 152, thereby limiting and/or preventing re-diffusion of oxygen ions from the ion storage layer 147 to the resistance switching layer 143. The plurality of diffusion barrier layers 156, 154, . . . , and 152 may have substantially the same thickness t3c, t3b, . . . , and t3a (ta in FIG. 3B), but the example embodiments are not limited thereto.

Ion diffusion coefficients and thicknesses of the plurality of diffusion barrier layers 156, 154, . . . , and 152, forming the diffusion barrier structure 150, may be controlled to achieve an improved degree of ion diffusion, thereby inducing a diffusion prevention effect.

In a transition metal oxide, when concentrations of oxygen components vary, the degree of the ionization may vary, and accordingly ion diffusion coefficients may be different from each other. Specifically, in a metal oxide group including the same metal material, it may be understood that an ion diffusion coefficient may decrease as an oxygen concentration increases.

The graph of FIG. 4 illustrates a degree of ion diffusion according to a thickness of a transition metal oxide. In the graph of FIG. 4, an X-axis may represent a voltage pulse number, and a Y-axis may represent a normalized conductivity. In FIG. 4, a thickness of the diffusion barrier structure 150 was varied to 2.5 nm, 5 nm, and 7.5 nm, and a normalized conductivity at each thickness was calculated. It may be understood that a higher normalized conductivity indicates a greater degree of ion diffusion.

According to FIG. 4, when a voltage pulse number is less than or equal to a desired (and/or alternatively predetermined) voltage pulse number, a conductivity according to a thickness may trend substantially linear. However, when the voltage pulse number is greater than the desired (and/or alternatively predetermined) voltage pulse number, the conductivity according to a greater thickness may exhibit a relatively linear variation, and a conductivity according to a lesser thickness may deviate from such linearity, and may exhibit a more rapid change in the conductivity trend. Such deviation from linearity may indicate that normalized conductivity is more unpredictable, from which potential memory loss due to rapid diffusion may be inferred.

The diffusion barrier structure 150 may be optimized to allow oxygen ions to reach the ion storage layer 147 through tunneling, and thus it may be difficult to increase a thickness thereof. In addition, in the channel hole having a limited size, the thickness of the diffusion barrier structure 150 may not be limitlessly increased. Accordingly, the thickness and a material of the diffusion barrier structure 150 may be controlled, such that the plurality of diffusion barrier layers 156, 154, . . . , and 152 may be stacked in multiple layers to reduce (and/or minimize) ion re-diffusion, thereby inducing an effect similar to that of a single diffusion barrier structure 150 having a thickness, greater than the third thickness t3. At the interfaces between the diffusion barrier layers 156, 154, . . . , and 152, oxygen ions may be unable to move to diffusion barrier layers 156, 154, . . . , and 152 in contact therewith due to interfacial resistance.

In FIGS. 3A and 3B, it may be understood that even when the plurality of diffusion barrier layers 156, 154, . . . , and 152 of the diffusion barrier structure 150 have the same thicknesses t3c, t3b, . . . , and t3a and include the same material, and thus has the same ion diffusion coefficient Da, re-diffusion of oxygen ions is sufficiently reduced and/or prevented due to the suppression of oxygen ion movement at the interfaces between the diffusion barrier layers 156, 154, . . . , and 152.

The electrolyte layer 145 may be disposed on the diffusion barrier structure 150 to cover an external surface and a bottom surface of the diffusion barrier structure 150.

The electrolyte layer 145 includes a metal oxide, and may include a transition metal oxide such as HfOₓ, ZrOₓ, YSZ, Ta₂O₅, or the like. The electrolyte layer 145 may include a material having an ionization tendency higher than that of the diffusion barrier structure 150. When respective layers of the diffusion barrier structure 150 include hafnium oxide, the electrolyte layer 145 may include tantalum oxide, but the present inventive concepts are not limited thereto. When the respective layers of the diffusion barrier structure 150 include hafnium oxide, the electrolyte layer 145 may also include hafnium oxide. However, an oxygen concentration of the electrolyte layer 145 may be lower than an oxygen concentration of the diffusion barrier structure 150. A fourth thickness t4 of the electrolyte layer 145 may be substantially the same as the first thickness t1 of the channel layer 140.

The ion storage layer 147 may be disposed to cover an external surface and a bottom surface of the electrolyte layer 145. The ion storage layer 147 may include a metal oxide, and may include a transition metal oxide such as WOₓ, GdOₓ, MoO_{y}, Ta₂O₅, Al₂O₃, TiOₓ, HfOₓ, SiOₓ, or the like. The ion storage layer 147 may perform a function the same as that of a charge trap layer in which data of a memory cell is stored by acquiring and storing oxygen ions generated in the resistance switching layer 143. The ion storage layer 147 may include a material having a higher ion diffusion coefficient to facilitate loss and acquisition of oxygen ions. However, when the ion storage layer 147 and the resistance switching layer 143 include tungsten oxide, an oxygen concentration of the ion storage layer 147 may be higher than that of the resistance switching layer 143. Accordingly, an ion diffusion coefficient of the ion storage layer 147 may be less than an ion diffusion coefficient of the resistance switching layer 143. A fifth thickness t5 of the ion storage layer 147 may be substantially the same as the first thickness t1 of the channel layer 140.

As illustrated in FIG. 1B, when viewed in X-Y plane, each of the channel structures CH may have the buried insulating layer 160 in the center O of channel hole as a circular or elliptical insulating pillar structure disposed with respect to the center O of the channel structure CH, an annular channel layer 140 may be disposed to surround a side surface of the buried insulating layer 160, and an annular resistance switching layer 143 may be disposed to surround an external surface of the annular channel layer 140. The respective layers of the diffusion barrier structure 150 are sequentially disposed to have an annular shape, and the annular electrolyte layer 145 may be disposed to surround an external surface of the diffusion barrier structure 150, that is, an external surface of an outermost diffusion barrier layer 156. The annular ion storage layer 147 may be disposed to surround an external surface of the electrolyte layer 145 and to be in contact with an external surface of the channel hole. Accordingly, from the channel layer 140 to the ion storage layer 147, all of the layers may have a ring shape having a concentric ring O and may be disposed to have an increasing radius.

The channel structure CH may include a first channel structure CH1 and a second channel structure CH2 respectively passing through the stack structures GS1 and GS2, and may include a bent portion between the first channel structure CH1 and the second channel structure CH2.

The channel layer 140, the resistance switching layer 143, the diffusion barrier structure 150, the electrolyte layer 145, and the ion storage layer 147 may be connected to each other between the first channel structure CH1 and the second channel structure CH2, and the channel pad 165 may be disposed only on an upper end of the second channel structure CH2.

The upper isolation regions US may extend in the X-direction between adjacent isolation regions MS in the Y-direction. The upper isolation regions US may be disposed to pass through a portion of the upper gate electrodes 130U, including an uppermost gate electrode 130U, among the gate electrodes 130. The number of upper gate electrodes 130U isolated by the upper isolation regions US may be changed in various manners according to some example embodiments. The upper isolation region US may be disposed to cross a portion of the channel structures CH. The upper isolation regions US may have a desired (and/or alternatively predetermined) width in the Y-direction, and may extend while crossing a plurality of channel structures CH, arranged in a zigzag matrix pattern, in the X-direction. Accordingly, when the plurality of channel structures CH are arranged to have the same separation distance, the upper isolation region US may extend while simultaneously crossing two consecutive rows of channel structures CH. The upper isolation region US may be recessed as a portion of the channel structure CH opposing upper ends of the two rows of channel structures CH, and accordingly, a portion of the channel structures CH may be removed. The upper isolation region US may not pass through a channel center of the channel structure CH, and may be disposed such that at least ½ of the channel structure CH remains on an upper surface thereof, but the example embodiments are not limited thereto. The channel structures CH into which the upper isolation region US is recessed may be effective channel structures substantially functioning as a memory cell, rather than a dummy channel structure. The upper isolation regions US may include an upper isolation insulating layer 103. The upper isolation insulating layer 103 may include an insulating material, and may include, for example, silicon oxide, silicon nitride, or silicon oxynitride. However, example embodiments are not limited thereto.

The isolation regions MS may extend in the X-direction through the gate electrodes 130, the interlayer insulating layers 120, and the first and second horizontal conductive layers 102 and 104, and may be connected to the semiconductor substrate 101. As illustrated in FIG. 1, the isolation regions MS may be disposed to be parallel to each other. The isolation regions MS may isolate the gate electrodes 130 from each other in the Y-direction. The isolation regions MS may have a width decreasing toward the semiconductor substrate 101 due to a high aspect ratio. The isolation regions MS may include an isolation insulating layer disposed in a trench. The isolation insulating layer may include an insulating material, for example, silicon oxide, silicon nitride, or silicon oxynitride. However, example embodiments are not limited thereto.

The contact plugs 170 may be disposed on the channel structures CH. The contact plugs 170 may have a cylindrical shape, and may have an inclined side surface such that a width thereof decreases toward the semiconductor substrate 101 depending on an aspect ratio. The contact plugs 170 may electrically connect the channel structures CH to an upper interconnection structure such as bit lines. The contact plugs 170 may be formed of a conductive material, and may include at least one of, for example, tungsten (W), aluminum (Al), and copper (Cu). However, example embodiments are not limited thereto.

The cell region insulating layer 192 may have a plurality of layer structures, and may be disposed to cover the gate electrodes 130 and to cover the isolation regions MS and US and the channel structures CH. Each of the cell region insulating layers 192 may be formed of an insulating material, and may include at least one of, for example, silicon oxide, silicon nitride, and silicon oxynitride. However, example embodiments are not limited thereto.

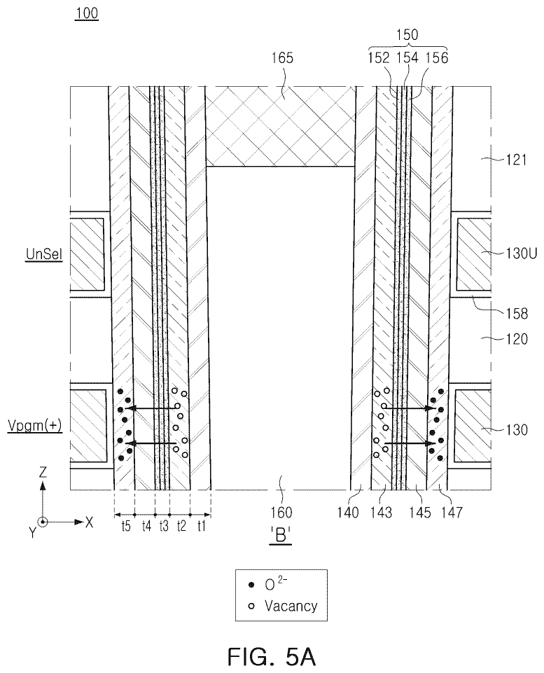

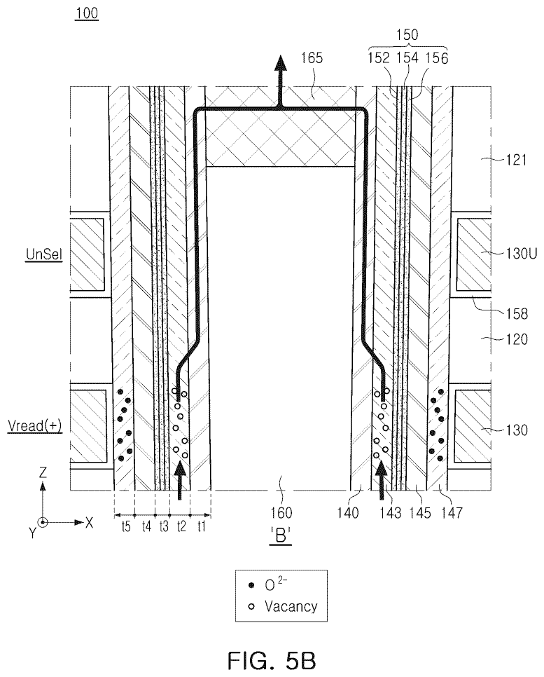

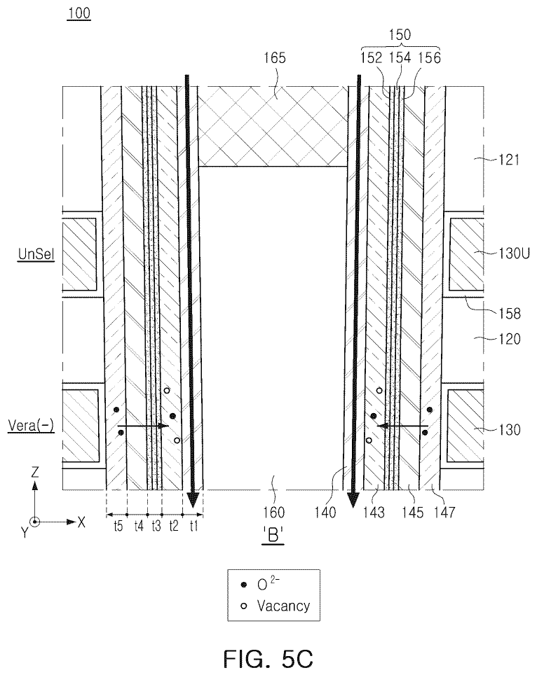

Hereinafter, an operation of the semiconductor device 100 including a memory cell will be described with reference to FIGS. 5A to 5C.

FIG. 5A is a state diagram during a program operation of a semiconductor device according to some example embodiments of the present inventive concepts, FIG. 5B is a state diagram during a read operation of the semiconductor device according to some example embodiments, and FIG. 5C is a state diagram during an erase operation of the semiconductor device according to some example embodiments.

A region of each channel structure CH corresponding to the gate electrode 130 may be a single memory cell transistor, an operation may be performed by a word line signal applied from the gate electrode 130, and a current, flowing between a source structure SS that may be a source and a channel pad 165 that may be a drain, may flow toward a bit line BL through the channel pad 165, and accordingly a state of a memory cell may be identified.

In FIG. 5A, when the second gate electrode 130 is selected and a program voltage Vpgm is applied, by the program voltage Vpgm, a positive (+) voltage, a metal oxide of the resistance switching layer 143 may be decomposed by an electrochemical reaction. Accordingly, oxygen ions may tunnel the diffusion barrier structure 150 and the electrolyte layer 145, and may be subsequently diffused into the ion storage layer 147. Such movement (diffusion) of oxygen ions may increase the concentration of oxygen ions in the ion storage layer 147 and decrease oxygen ions in the resistance switching layer 143, thereby maintaining a state with a significant number of oxygen vacancies in the transition metal oxide in the resistance switching layer 143. As oxygen ions are accumulated in the ion storage layer 147 as carriers, it may be considered that data is stored (programmed) in a corresponding memory cell.

When a read operation is performed in FIG. 5B, a read voltage Vread may be applied to a gate electrode 130 of a programmed memory cell.

During the read operation in which the read voltage Vread is applied to the gate electrode 130 of the programmed memory cell, a current (indicated by an arrow) may flow from the source structure SS to the channel pad 165 that may be a drain. Accordingly, a current according to programmed data may flow to the bit line BL through the channel pad 165 that may be a drain. In this case, the current may flow along the channel layer 140 and may then flow along the resistance switching layer 143 having a lower resistance due to oxygen vacancies in a corresponding memory cell. Accordingly, the read operation may include a current flowing along the channel layer 140 and the resistance switching layer 143 opposing the gate electrode 130 of the programmed memory cell.

As illustrated in FIG. 5C, when the erase operation is performed, an erase voltage Vera, a negative (−) voltage, may be applied to the gate electrodes 130, the word lines. The erase voltage Vera may allow oxygen ions in the ion storage layer 147 to move (diffuse) toward the channel layer 140 due to a repulsive force, and the oxygen ions may pass through the electrolyte layer 145 and the diffusion barrier structure 150, and may be rearranged into oxygen vacancies in the resistance switching layer 143. Accordingly, the oxygen vacancies may be removed by the gain of oxygen ions, and thus the oxygen vacancies in the resistance switching layer 143 may be (significantly) reduced, thereby increasing the resistance value again. Such an increase in the resistance value of the resistance switching layer 143 may allow a current flowing from the source structure SS to the channel pad 165 to continue to flow along the channel layer 140, rather than to flow along the resistance switching layer 143 on the memory cell. Accordingly, it may be considered that the oxygen ions accumulated in the ion storage layer 147 are removed to perform the erase operation. In the some example embodiments, a current path in the channel structure CH during the read operation may differ from a current path during the erase operation. That is, it may be understood that the current path may bypass during the read operation. Accordingly, the resistance switching layer 143 and the channel layer 140 may function together as a current path, as an ion-providing structure.

The semiconductor device 100 may be defined as an electrochemical random-access memory (ECRAM) storing data through an electrochemical reaction. To ensure that a programmed state is maintained for an extended period, retention efficiency may be secured in ECRAM. The diffusion barrier structure 150 may include a plurality of diffusion barrier layers 156, 154, . . . , and 152 to reduce and/or prevent oxygen ions accumulated in the ion storage layer 147 in the programmed state from being re-diffused through the electrolyte layer 145 and the diffusion barrier structure 150.

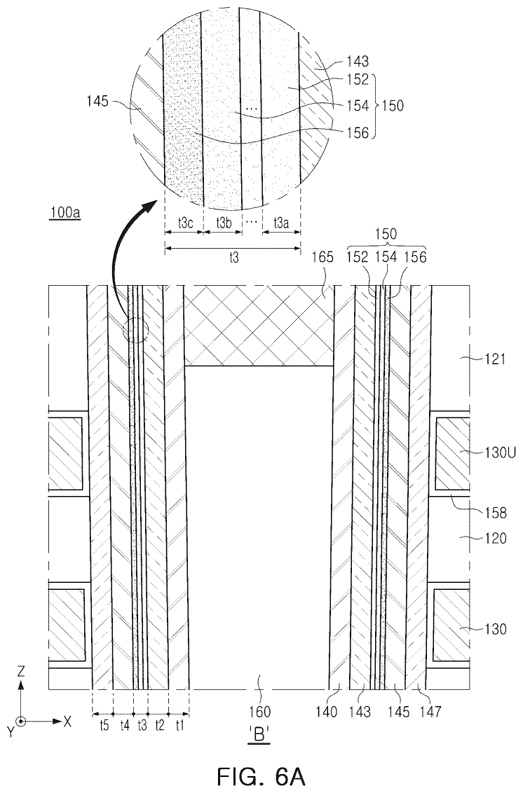

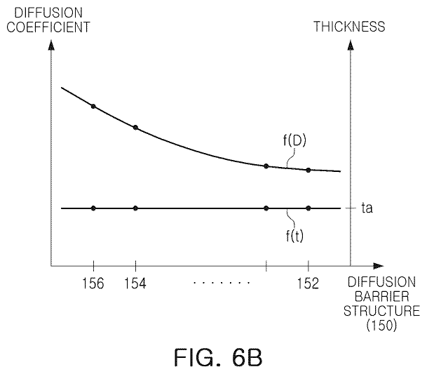

Hereinafter, example embodiments will be described with reference to FIGS. 6A to 17.

FIGS. 6A, 7A, 8A, 9A, FIG. 10A, FIG. 11A, FIG. 12A, FIG. 13A, FIG. 14A, FIG. 15A, FIG. 16, and FIG. 17 are partially enlarged views corresponding to FIG. 3A.

FIGS. 6B, 7B, 8B, 9B, 10B, 11B, 12B, 13B, 14B, and 15B may be graphs illustrating characteristics of a diffusion barrier structure 150 in each semiconductor device corresponding to FIG. 3B. Each graph may include an ion diffusion coefficient f(D) and a thickness f(t) of each of the diffusion barrier layers 156, 154, . . . , and 152.

Referring to FIGS. 6A and 6B, a semiconductor device 100a may be the same as that of FIGS. 1 to 3A, except for a diffusion barrier structure 150 of channel structures CH. Specifically, the diffusion barrier structure 150 may include a plurality of diffusion barrier layers 156, 154, . . . , and 152, and the plurality of diffusion barrier layers 156, 154, . . . , and 152, sequentially stacked on a channel layer 140, may include different materials. Each of the plurality of diffusion barrier layers 156, 154, . . . , and 152 may include a metal oxide, and may include at least one of WOₓ, HfO_{y}, and AlOₓ, as a transition metal oxide. However, example embodiments are not limited thereto.

The plurality of diffusion barrier layers 156, 154, . . . , and 152 may include materials having a smaller ion diffusion coefficient f(D) between an electrolyte layer 145 and a resistance switching layer 143 as a distance from the electrolyte layer 145 increases. For example, a metal oxide including the same metal may be included, and an oxygen concentration in the metal oxide may increase as a distance from the resistance switching layer 143 decreases. For example, when hafnium oxide is included, an oxygen concentration in a compound may increase as the distance from the resistance switching layer 143 decreases. The metal oxides having different oxygen concentrations may result different ion diffusion coefficients f(D) in the diffusion barrier layers 156, 154, ... and 152, thereby further enhancing the blocking of ion diffusion at interfaces between the diffusion barrier layers 156, 154, . . . , and 152. Even in this case, thicknesses f(t) of the diffusion barrier layers 156, 154, . . . , and 152 may be the same.

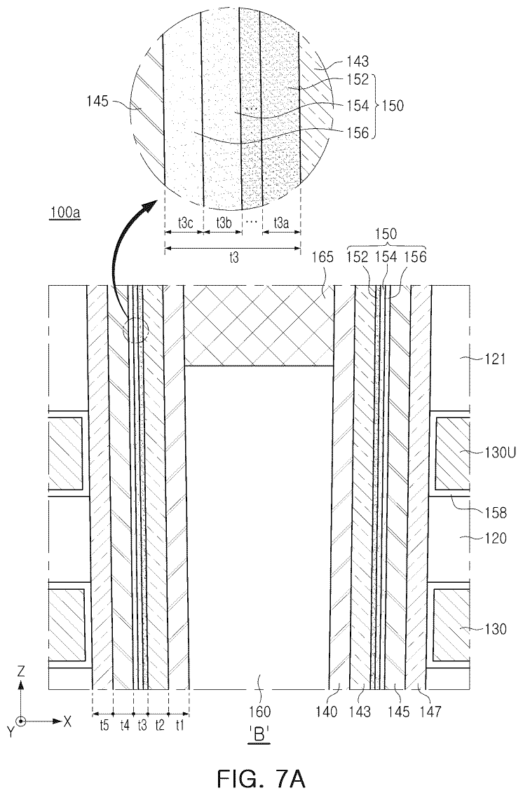

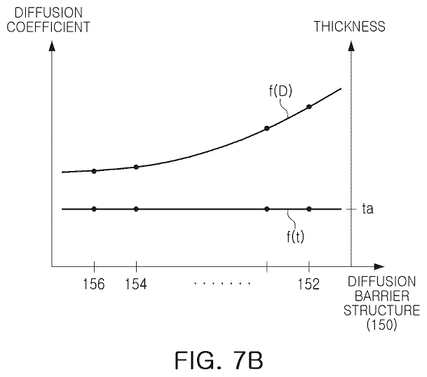

Referring to FIGS. 7A and 7B, a semiconductor device 100b may be the same as that of FIGS. 1 to 3A except for a diffusion barrier structure 150 of channel structures CH. Specifically, the diffusion barrier structure 150 may include a plurality of diffusion barrier layers 156, 154, . . . , and 152, and the plurality of diffusion barrier layers 156, 154, . . . , and 152, sequentially stacked on a channel layer 140, may include different materials. Each of the plurality of diffusion barrier layers 156, 154, . . . , and 152 may include a metal oxide, and may include at least one of WOₓ, HfO_{y}, and AlOₓ, as a transition metal oxide. However, example embodiments are not limited thereto.

The plurality of diffusion barrier layers 156, 154, . . . , and 152 may include materials having a larger ion diffusion coefficient f(D) between an electrolyte layer 145 and a resistance switching layer 143 as a distance from the electrolyte layer 145 increases. For example, a metal oxide including the same metal may be included, and an oxygen concentration in the metal oxide may decrease as a distance from the resistance switching layer 143 decreases. For example, when hafnium oxide is included, an oxygen concentration in a compound may decrease as the distance from the resistance switching layer 143 decreases. The metal oxides having different oxygen concentrations may result different ion diffusion coefficients f(D) in the diffusion barrier layers 156, 154, . . . and 152, thereby further enhancing the blocking of ion diffusion at interfaces between the diffusion barrier layers. Even in this case, thicknesses f(t) of the diffusion barrier layers 156, 154, . . . , and 152 may be the same.

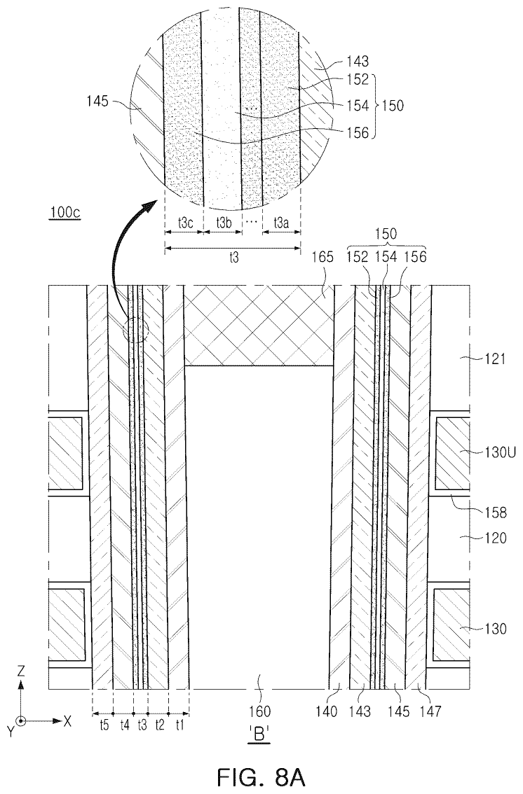

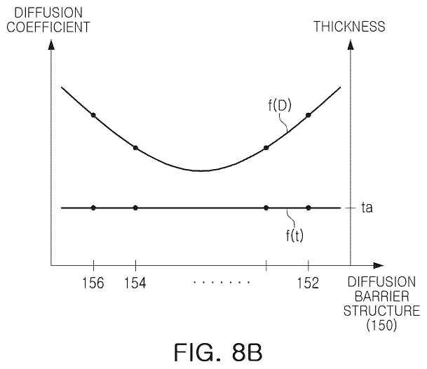

Referring to FIGS. 8A and 8B, a semiconductor device 100c may be the same as that of FIGS. 1 to 3A except for a diffusion barrier structure 150 of channel structures CH. Specifically, the diffusion barrier structure 150 may include a plurality of diffusion barrier layers 156, 154, . . . , and 152, and the plurality of diffusion barrier layers 156, 154, . . . , and 152, sequentially stacked on a channel layer 140, may include different materials. Each of the plurality of diffusion barrier layers 156, 154, . . . , and 152 may include a metal oxide, and may include at least one of WOₓ, HfO_{y}, and AlOₓ, as a transition metal oxide. However, example embodiments may not be limited thereto.

The plurality of diffusion barrier layers 156, 154, . . . , and 152 may include materials having a smaller ion diffusion coefficient f(D) between an electrolyte layer 145 and a resistance switching layer 143 as a distance from the electrolyte layer 145 and the resistance switching layer 143 increases. For example, a metal oxide including the same metal may be included, and a metal oxide of an intermediate diffusion barrier layer may have a higher oxygen concentration. For example, when hafnium oxide is included, an oxygen concentration in a compound may increase as the distance from the electrolyte layer 145 and the resistance switching layer 143 increases. The metal oxides having different oxygen concentrations may result different ion diffusion coefficients f(D) in the diffusion barrier layers 156, 154, . . . and 152, thereby further enhancing the blocking of ion diffusion at interfaces between the diffusion barrier layers 156, 154, . . . and 152. Even in this case, thicknesses f(t) of the diffusion barrier layers 156, 154, . . . , and 152 may be the same.

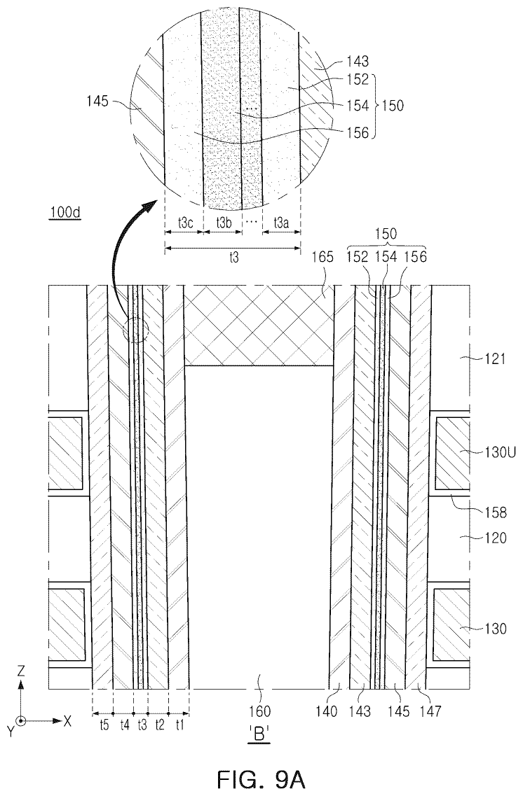

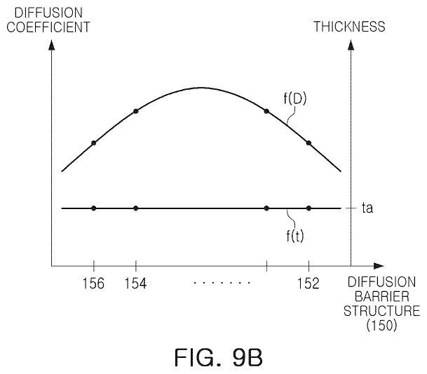

Referring to FIGS. 9A and 9B, a semiconductor device 100d may be the same as that of FIGS. 1 to 3A except for a diffusion barrier structure 150 of channel structures CH. Specifically, the diffusion barrier structure 150 may include a plurality of diffusion barrier layers 156, 154, . . . , and 152, and the plurality of diffusion barrier layers 156, 154, . . . , and 152, sequentially stacked on a channel layer 140, may include different materials. Each of the plurality of diffusion barrier layers 156, 154, . . . , and 152 may include a metal oxide, and may include at least one of WOₓ, HfO_{y}, and AlOₓ, as a transition metal oxide. However, example embodiments may not be limited thereto.

The plurality of diffusion barrier layers 156, 154, . . . , and 152 may include materials having a larger ion diffusion coefficient f(D) between an electrolyte layer 145 and a resistance switching layer 143 as a distance from the electrolyte layer 145 and the resistance switching layer 143 increases. For example, a metal oxide including the same metal may be included, and a metal oxide of an intermediate diffusion barrier layer may have a lower oxygen concentration. For example, when hafnium oxide is included, an oxygen concentration in a compound may decrease as the distance from the electrolyte layer 145 and the resistance switching layer 143 increases. The metal oxides having different oxygen concentrations may result different ion diffusion coefficients f(D) in the diffusion barrier layers 156, 154, . . . and 152, thereby further enhancing the blocking of ion diffusion at interfaces between the diffusion barrier layers 156, 154, . . . and 152. Even in this case, thicknesses f(t) of the diffusion barrier layers 156, 154, . . . , and 152 may be the same.

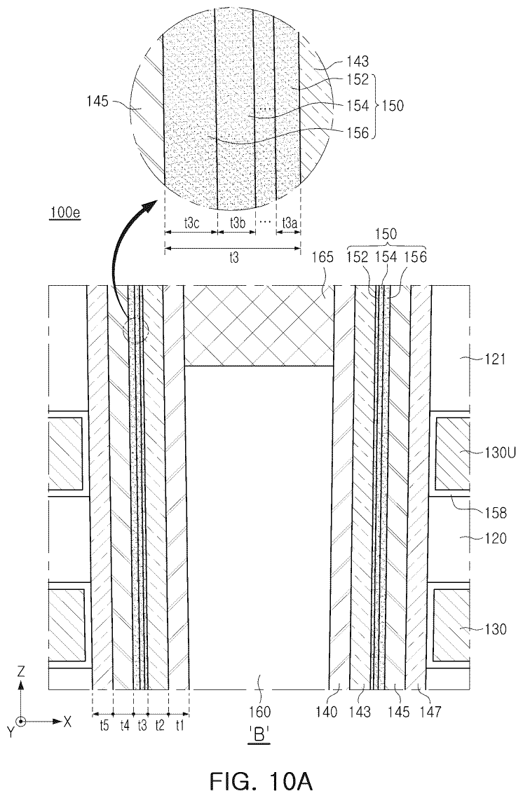

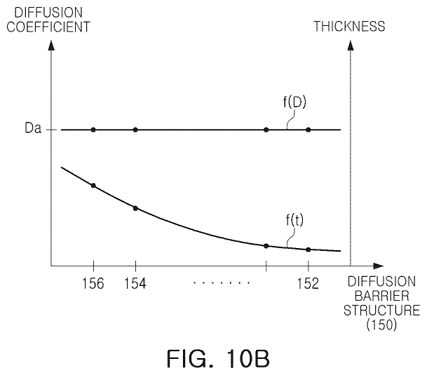

Referring to FIGS. 10A and 10B, a semiconductor device 100e may be the same as that of FIGS. 1 to 3A except for a diffusion barrier structure 150 of channel structures CH. Specifically, the diffusion barrier structure 150 may include a plurality of diffusion barrier layers 156, 154, . . . , and 152, and the plurality of diffusion barrier layers 156, 154, . . . , and 152, sequentially stacked on a channel layer 140, may include the same material. Each of the plurality of diffusion barrier layers 156, 154, . . . , and 152 may include a metal oxide, and may include at least one of WOₓ, HfO_{y}, and AlOₓ, as a transition metal oxide. However, example embodiments may not be limited thereto.

The plurality of diffusion barrier layers 156, 154, . . . , and 152 may have different thicknesses f(t) between an electrolyte layer 145 and a resistance switching layer 143. The plurality of diffusion barrier layers 156, 154, . . . , and 152 may have a reduced thickness as a distance from the electrolyte layer 145 increases. As illustrated in FIG. 4, when the thickness varies, each of the diffusion barrier layers 156, 154, . . . , and 152 may have a varying conductivity, and accordingly a degree of diffusion of oxygen ions may change, thereby further enhancing the blocking of ion diffusion at interfaces between the diffusion barrier layers 156, 154, . . . and 152.

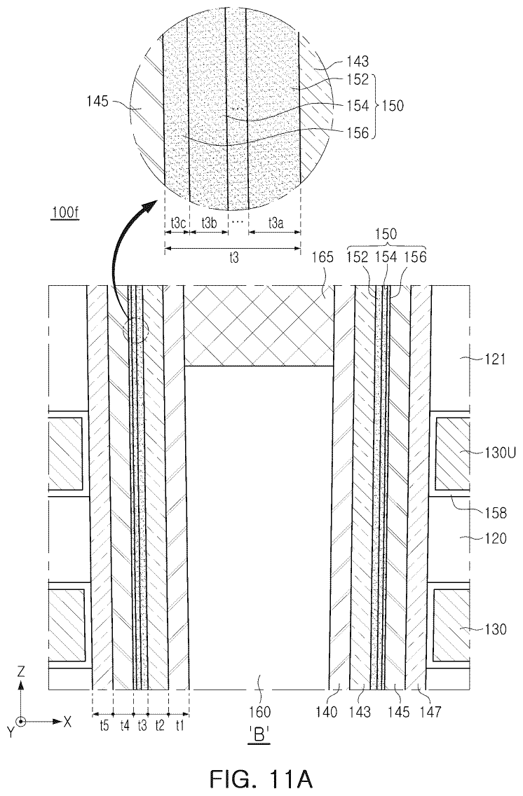

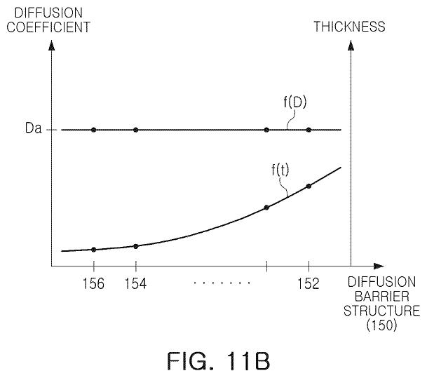

Referring to FIGS. 11A and 11B, a semiconductor device 100f may be the same as that of FIGS. 1 to 3A except for a diffusion barrier structure 150 of channel structures CH. Specifically, the diffusion barrier structure 150 may include a plurality of diffusion barrier layers 156, 154, . . . , and 152, and the plurality of diffusion barrier layers 156, 154, . . . , and 152, sequentially stacked on a channel layer 140, may include the same material. Each of the plurality of diffusion barrier layers 156, 154, . . . , and 152 may include a metal oxide, and may include at least one of WOₓ, HfO_{y}, and AlOₓ, as a transition metal oxide. However, example embodiments may not be limited thereto.

The plurality of diffusion barrier layers 156, 154, . . . , and 152 may have different thicknesses f(t) between an electrolyte layer 145 and a resistance switching layer 143. The plurality of diffusion barrier layers 156, 154, . . . , and 152 may have an increased thickness f(t) as a distance from the electrolyte layer 145 increases. As illustrated in FIG. 4, when the thickness f(t) varies, each of the diffusion barrier layers 156, 154, . . . , and 152 may have a varying conductivity, and accordingly a degree of diffusion of oxygen ions may change, thereby further enhancing the blocking of ion diffusion at interfaces between the diffusion barrier layers 156, 154, . . . and 152.

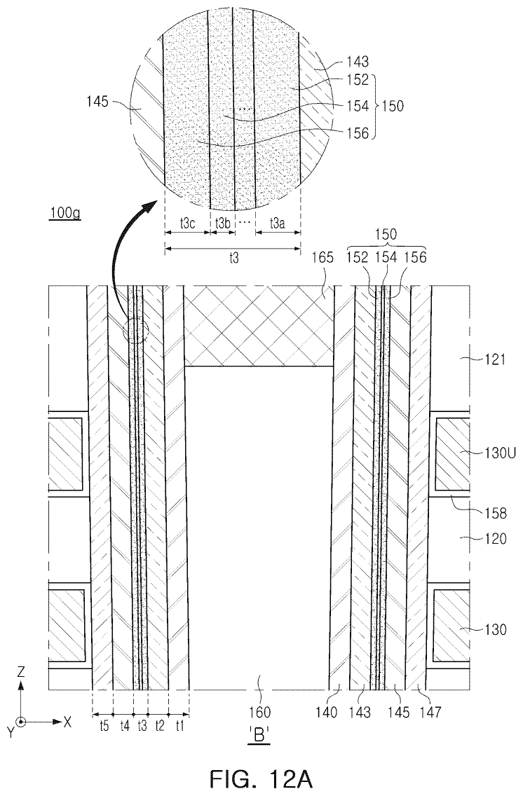

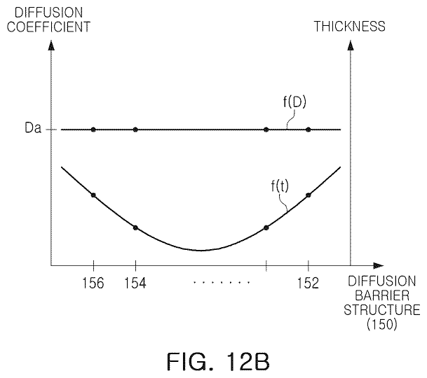

Referring to FIGS. 12A and 12B, a semiconductor device 100g may be the same as that of FIGS. 1 to 3A except for a diffusion barrier structure 150 of channel structures CH. Specifically, the diffusion barrier structure 150 may include a plurality of diffusion barrier layers 156, 154, . . . , and 152, and the plurality of diffusion barrier layers, sequentially stacked on a channel layer 140, may include the same material. Each of the plurality of diffusion barrier layers 156, 154, . . . , and 152 may include a metal oxide, and may include at least one of WOₓ, HfO_{y}, and AlOₓ, as a transition metal oxide. However, example embodiments may not be limited thereto.

The plurality of diffusion barrier layers 156, 154, . . . , and 152 may have different thicknesses f(D) between an electrolyte layer 145 and a resistance switching layer 143. As a distance from the electrolyte layer 145 and the resistance switching layer 143 increases, the plurality of diffusion barrier layers 156, 154, . . . , and 152 may have a reduced thickness f(D), such that an intermediate diffusion barrier layer may have a smaller thickness f(D). When the thickness f(D) varies, each of the diffusion barrier layers 156, 154, . . . , and 152 may have a varying conductivity, and accordingly a degree of diffusion of oxygen ions may change, thereby further enhancing the blocking of ion diffusion at interfaces between the diffusion barrier layers 156, 154, . . . and 152.

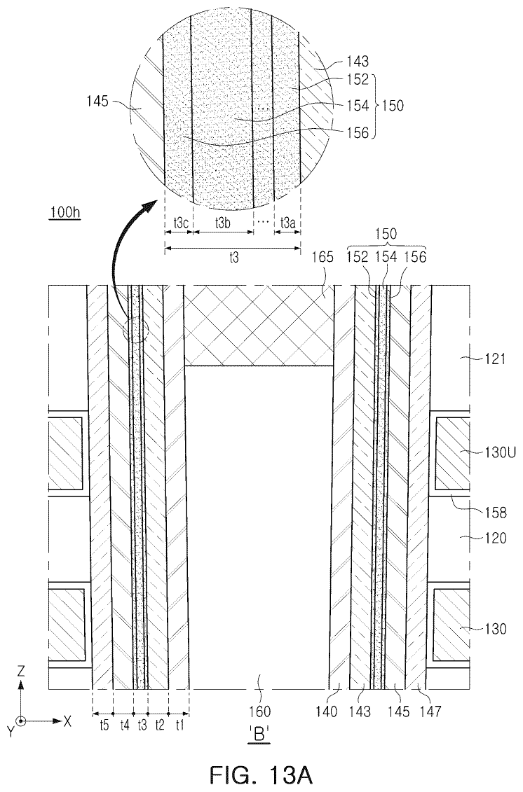

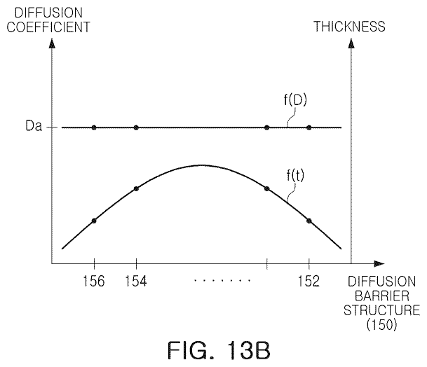

Referring to FIGS. 13A and 13B, a semiconductor device 100h may be the same as that of FIGS. 1 to 3A except for a diffusion barrier structure 150 of channel structures CH. Specifically, the diffusion barrier structure 150 may include a plurality of diffusion barrier layers 156, 154, . . . , and 152, and the plurality of diffusion barrier layers, sequentially stacked on a channel layer 140, may include the same material. Each of the plurality of diffusion barrier layers 156, 154, . . . , and 152 may include a metal oxide, and may include at least one of WOₓ, HfO_{y}, and AlOₓ, as a transition metal oxide. However, example embodiments may not be limited thereto.

The plurality of diffusion barrier layers 156, 154, . . . , and 152 may have different thicknesses f(D) between an electrolyte layer 145 and a resistance switching layer 143. As a distance from the electrolyte layer 145 and the resistance switching layer 143 increases, the plurality of diffusion barrier layers 156, 154, . . . , and 152 may have an increased thickness f(D), such that an intermediate diffusion barrier layer may have a larger thickness f(D). When the thickness f(D) varies, each of the diffusion barrier layers 156, 154, . . . , and 152 may have a varying conductivity, and accordingly a degree of diffusion of oxygen ions may change, thereby further enhancing the blocking of ion diffusion at interfaces between the diffusion barrier layers 156, 154, . . . and 152.

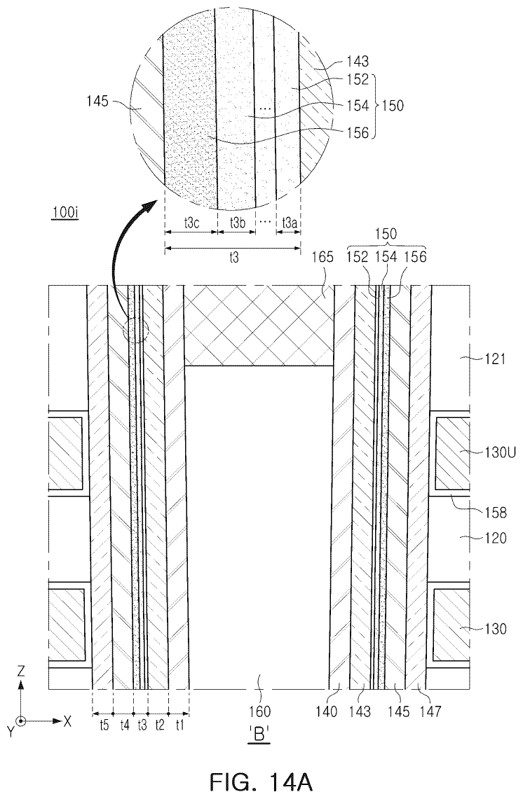

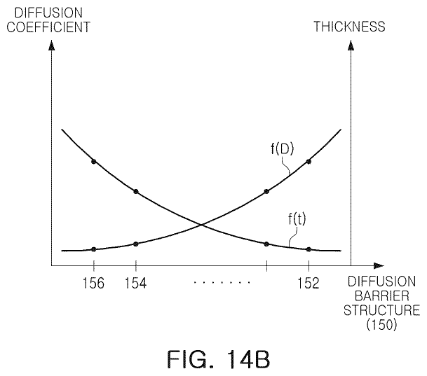

Referring to FIGS. 14A and 14B, a semiconductor device 100h may be the same as that of FIGS. 1 to 3A except for a diffusion barrier structure 150 of channel structures CH. Specifically, the diffusion barrier structure 150 may include a plurality of diffusion barrier layers 156, 154, . . . , and 152, and the plurality of diffusion barrier layers 156, 154, . . . , and 152, sequentially stacked on a channel layer 140, may include different materials. Each of the plurality of diffusion barrier layers 156, 154, . . . , and 152 may include a metal oxide, and may include at least one of WOₓ, HfO_{y}, and AlOₓ, as a transition metal oxide. However, example embodiments may not be limited thereto. The plurality of diffusion barrier layers 156, 154, . . . , and 152 may include materials having a larger ion diffusion coefficient f(D) between an electrolyte layer 145 and a resistance switching layer 143 as a distance from the electrolyte layer 145 increases. For example, a metal oxide including the same metal may be included, and metal oxides of diffusion barrier layers 156, 154, . . . , and 152, disposed to be close to the resistance switching layer 143, may have a lower oxygen concentration. For example, when hafnium oxide is included, an oxygen concentration in a compound may decrease as the distance from the electrolyte layer 145 decreases. The metal oxides having different oxygen concentrations may result different ion diffusion coefficients f(D) in the diffusion barrier layers 156, 154, . . . and 152, thereby further enhancing the blocking of ion diffusion at interfaces between the diffusion barrier layers 156, 154, . . . , and 152.

The plurality of diffusion barrier layers 156, 154, . . . , and 152 may have different thicknesses f(t) between an electrolyte layer 145 and a resistance switching layer 143. The plurality of diffusion barrier layers 156, 154, . . . , and 152 may have a reduced thickness f(t) as a distance from the electrolyte layer 145 increases. When the thickness f(t) varies, each of the diffusion barrier layers 156, 154, . . . , and 152 may have a varying conductivity, and accordingly a degree of diffusion of oxygen ions may change, thereby further enhancing the blocking of ion diffusion at interfaces between the diffusion barrier layers 156, 154, . . . and 152.

As described, both the thicknesses f(t) and the ion diffusion coefficients f(D) of the plurality of diffusion barrier layers 156, 154, . . . and 152, forming a stacked structure, may be controlled, thereby achieving improved diffusion prevention efficiency.

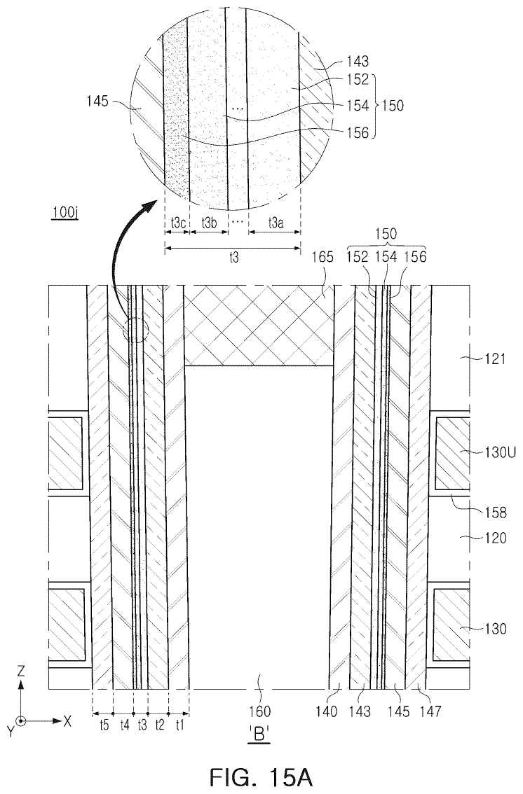

Referring to FIGS. 15A and 15B, a semiconductor device 100j may be the same as that of FIGS. 1 to 3A except for a diffusion barrier structure 150 of channel structures CH. Specifically, the diffusion barrier structure 150 may include a plurality of diffusion barrier layers 156, 154, . . . , and 152, and the plurality of diffusion barrier layers, sequentially stacked on a channel layer 140, may include different materials. Each of the plurality of diffusion barrier layers 156, 154, . . . , and 152 may include a metal oxide, and may include at least one of WOₓ, HfO_{y}, and AlOₓ, as a transition metal oxide. However, example embodiments may not be limited thereto. The plurality of diffusion barrier layers 156, 154, . . . , and 152 may include materials having a smaller ion diffusion coefficient f(D) between an electrolyte layer 145 and a resistance switching layer 143 as a distance from the electrolyte layer 145 increases. For example, a metal oxide including the same metal may be included, and a metal oxide of a diffusion barrier layer 152, disposed to be closed to the resistance switching layer 143, may have a higher oxygen concentration. For example, when hafnium oxide is included, an oxygen concentration in a compound may increase as the distance from the electrolyte layer 145 increases. The metal oxides having different oxygen concentrations may result different ion diffusion coefficients f(D) in the diffusion barrier layers 156, 154, . . . and 152, thereby further enhancing the blocking of ion diffusion at interfaces between the diffusion barrier layers 156, 154, . . . , and 152.

The plurality of diffusion barrier layers 156, 154, . . . , and 152 may have different thicknesses f(t) between an electrolyte layer 145 and a resistance switching layer 143. The plurality of diffusion barrier layers 156, 154, . . . , and 152 may have an increased thickness f(t) as a distance from the electrolyte layer 145 increases. When the thickness f(t) varies, each of the diffusion barrier layers 156, 154, . . . , and 152 may have a varying conductivity, and accordingly a degree of diffusion of oxygen ions may change, thereby further enhancing the blocking of ion diffusion at interfaces between the diffusion barrier layers 156, 154, . . . and 152.

As described, both the thicknesses f(t) and the ion diffusion coefficients f(D) of the plurality of diffusion barrier layers 156, 154, . . . and 152, forming a stacked structure, may be controlled, thereby achieving improved diffusion prevention efficiency.

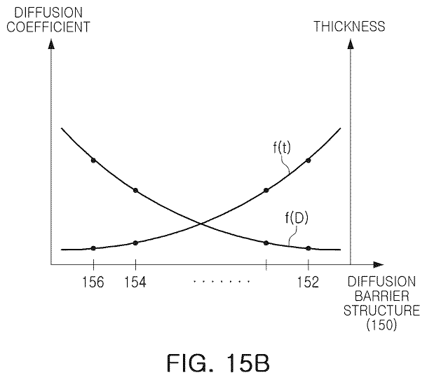

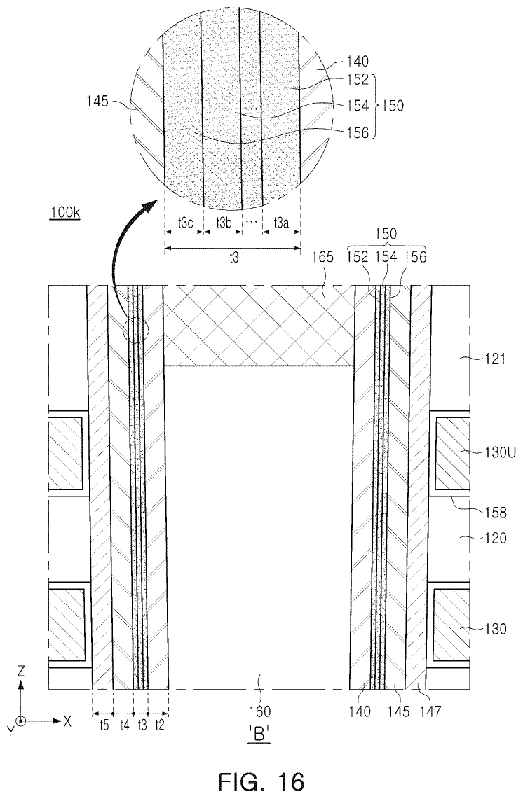

Referring to FIG. 16, a semiconductor device 100k may be the same as that of FIGS. 1 to 3A, except for a resistance switching layer 143 of channel structures CH. Specifically, the channel structure CH may surround an external surface and a bottom surface of a channel layer 140 without the resistance switching layer 143. In this case, the channel layer 140 may include a metal oxide-based semiconductor, instead of a silicon-based material. Accordingly, oxygen ions in the channel layer itself may be ionized by an electrochemical reaction and diffused into an ion storage layer. Since the resistance switching layer is not disposed, a resistance value of the channel layer may decrease due to the desorption of oxygen ions from the channel layer itself, thereby changing a threshold voltage.

Referring to FIG. 17, a semiconductor device 100l may be the same as that of FIGS. 1 to 3A A except for tunneling layers 161 and 163 of channel structures CH. Specifically, a channel structure may further include a plurality of tunneling layers 161 and 163.

A first tunneling layer 161 may be disposed between gate electrodes 130 and an ion storage layer 147.

A second tunneling layer 163 may be disposed between a channel layer 140 and a resistance switching layer 143.

The first tunneling layer 161 and the second tunneling layer 163 may have a thickness less than a first thickness t1 of the channel layer 140, and may have a thickness through which oxygen ions may be easily tunneled. The first and second tunneling layers 161 and 163 may include silicon oxide (SiO₂), silicon nitride (Si₃N₄), silicon oxynitride (SiON), or combinations thereof.

Hereinafter, a method of manufacturing a semiconductor device according to some example embodiments will be described.

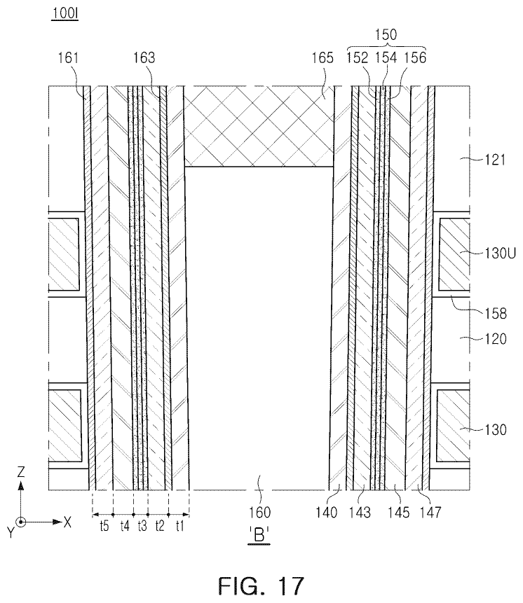

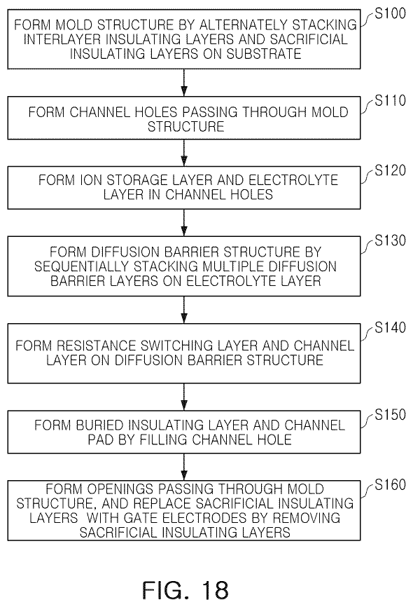

FIG. 18 is a flowchart illustrating a method of manufacturing the semiconductor device illustrated in FIGS. 1 to 3B.

Referring to FIG. 18, first and second mold structures may be formed by alternately stacking sacrificial insulating layers and interlayer insulating layers 120 (S100). Specifically, a first horizontal sacrificial layer and a second horizontal conductive layer may be first formed on a semiconductor substrate 101, and then vertical sacrificial layers passing through the first mold structure may be formed, and the second mold structure may be formed.

The sacrificial insulating layers may be layers replaced with the gate electrodes 130 (see FIG. 3A) through a subsequent process. The sacrificial insulating layers may be formed of a material that is different from that of the interlayer insulating layers 120, and may be formed of a material that may be etched with an etching selectivity with respect to the interlayer insulating layers 120 under a specific etching condition. For example, the interlayer insulating layers 120 may be formed of at least one of silicon oxide and silicon nitride, and the sacrificial insulating layers may be formed of a material that is different from that of the interlayer insulating layers 120 selected from silicon, silicon oxide, silicon carbide, and silicon nitride. However, example embodiments may not be limited thereto.

The vertical sacrificial layers may be formed in a region corresponding to the first channel structures CH1 of FIG. 3A. The vertical sacrificial layers may be formed by forming lower channel holes passing through the first mold structure, and then depositing a material, included in the vertical sacrificial layers, in the lower channel holes and performing a planarization process.

Subsequently, channel holes passing through the first and second mold structures may be formed (S110), and an ion storage layer 147 and an electrolyte layer 145 may be formed in the channel holes (S120).

The channel holes may be formed by anisotropically etching the first and second mold structures using a mask layer. The channel holes may be formed to recess a portion of the semiconductor substrate 101.

The ion storage layer 147 and the electrolyte layer 145 may be formed by sequentially depositing the ion storage layer 147 and the electrolyte layer 145 in the channel holes. The ion storage layer 147 and the electrolyte layer 145 may be formed to have a uniform (or substantially uniform) thickness using an atomic layer deposition (ALD) process or a chemical vapor deposition (CVD) process.

Subsequently, a diffusion barrier structure 150 may be formed on the electrolyte layer 145 (S130).

The diffusion barrier structure 150 may form each of the diffusion barrier layers 156, 154, . . . , and 152 by performing the ALD process or the CVD process while providing oxygen and metal particles having a concentration that satisfies a controlled thickness and ion diffusion coefficient with respect to each of the plurality of diffusion barrier layers 156, 154, . . . , and 152.

As described, each of the diffusion barrier layers 156, 154, . . . , and 152 may be formed through a deposition process, thereby generating an interface between the diffusion barrier layers 156, 154, . . . , and 152.

Subsequently, a resistance switching layer 143 and a channel layer 140 may be formed on the diffusion barrier structure 150 (S140). The resistance switching layer 143 may form a metal oxide having a desired (and/or alternatively predetermined) thickness by performing the ALD process or the CVD process. The channel layer 140 may be formed on the resistance switching layer 143. The channel layer 140 may be formed by depositing a metal oxide semiconductor, or may be formed by depositing a silicon semiconductor.

Subsequently, the channel structure of FIG. 3A may be formed by forming a buried insulating layer 160 as an insulating pillar in a center of the channel hole in the channel layer 140, and forming a channel pad 165 on an upper portion thereof (S150). The channel pad 165 may be formed by depositing a conductive material on the channel layer 140 while filling a space on the buried insulating layer 160 at upper ends of the channel holes. The channel pad 165 may be formed of a conductive material, and may have crystallinity different from that of the channel layer 140. For example, the channel pad may be formed of polycrystalline silicon. Subsequently, a chemical mechanical polishing (CMP) process may be performed from the polycrystalline silicon until an upper surface of an uppermost interlayer insulating layer 121 is exposed.

Subsequently, openings passing through the first and second mold structures may be formed, a first horizontal conductive layer 102 may be formed, and then tunnel portions may be formed by removing the sacrificial insulating layers (S160). Sacrificial spacer layers may be formed in the openings, an etch-back process may be performed to expose a horizontal sacrificial layer, and the horizontal sacrificial layer may be removed from an exposed region. The first horizontal conductive layer 102 may be formed by depositing a conductive material in a region from which the horizontal sacrificial layer is removed, and then the sacrificial spacer layers may be removed from the openings. Through the present process, a source structure SS including the semiconductor substrate 101 and the first and second horizontal conductive layers 102 and 104 may be formed.

The sacrificial insulating layers may be selectively removed with respect to the interlayer insulating layers 120, for example, using wet etching. Accordingly, a plurality of tunnel portions may be formed between the interlayer insulating layers 120. Gate electrodes 130 may be formed by filling the tunnel portions with a conductive material, and an isolation region MS may be formed by filling the opening, and then upper interconnection structures including contact plugs 170 may be formed to form the semiconductor device of FIG. 3A.

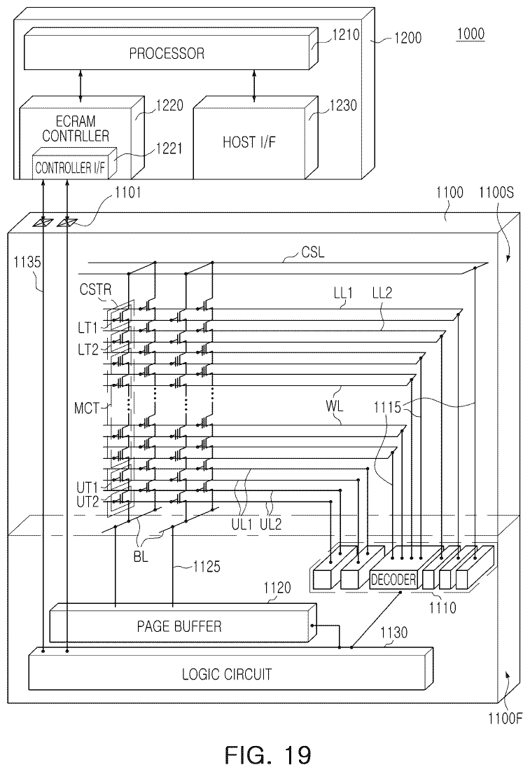

FIG. 19 is a schematic diagram illustrating a data storage system including a semiconductor device according to some example embodiments.

Referring to FIG. 19, a data storage system 1000 may include a semiconductor device 1100 and a controller 1200 electrically connected to the semiconductor device 1100. The data storage system 1000 may be a storage device including a single semiconductor device 1100 or a plurality of semiconductor devices 1100 or an electronic device including the storage device. For example, the data storage system 1000 may be a solid-state drive device (SSD) including the single semiconductor device 1100 or the plurality of semiconductor devices 1100, a universal serial bus (USB), a computing system, a medical device, or a communication device.

The semiconductor device 1100 may be a non-volatile memory device, and may be, for example, the ECRAM memory device described above with reference to FIGS. 1 to 17. The semiconductor device 1100 may include a first semiconductor structure 1100F and a second semiconductor structure 1100S on the first semiconductor structure 1100F. In some example embodiments, the first semiconductor structure 1100F may be disposed next to the second semiconductor structure 1100S. The first semiconductor structure 1100F may be a peripheral circuit structure including a decoder circuit 1110, a page buffer 1120, and a logic circuit 1130. The second semiconductor structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second semiconductor structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. In some example embodiments, the number of lower transistors LT1 and LT2 and the number of upper transistors UT1 and UT2 may be modified in various manners.

In some example embodiments, the upper transistors UT1 and UT2 may include a string selection transistor, and the lower transistors LT1 and LT2 may include a ground selection transistor. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

In some example embodiments, the lower transistors LT1 and LT2 may include a lower erase control transistor LT1 and a ground selection transistor LT2 connected in series. The upper transistors UT1 and UT2 may include a string selection transistor UT1 and an upper erase control transistor UT2 connected in series. At least one of the lower erase control transistor LT1 and the upper erase control transistor UT2 may be used for an erase operation of erasing data stored in the memory cell transistors MCT using a GIDL phenomenon.

The common source line CSL, the first and second gate lower lines LL1 and LL2, the word lines WL, and the first and second gate upper lines UL1 and UL2 may be electrically connected to the decoder circuit 1110 via first connection interconnections 1115 extending from an interior of the first semiconductor structure 1100F to the second semiconductor structure 1100S. The bit lines BL may be electrically connected to the page buffer 1120 via second connection interconnections 1125 extending from the interior of the first semiconductor structure 1100F to the second semiconductor structure 1100S.

In the first semiconductor structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. The semiconductor device 1100 may communicate with the controller 1200 via an input/output pad 1101 electrically connected to the logic circuit 1130. The input/output pad 1101 may be electrically connected to the logic circuit 1130 via an input/output connection interconnection 1135 extending from the interior of the first semiconductor structure 1100F to the second semiconductor structure 1100S.

The controller 1200 may include a processor 1210, an ECRAM controller 1220, and a host interface 1230. In some example embodiments, the data storage system 1000 may include a plurality of semiconductor devices 1100. In this case, the controller 1200 may control the plurality of semiconductor devices 1100.

The processor 1210 may control an overall operation of the data storage system 1000 including the controller 1200. The processor 1210 may operate according to desired (and/or alternatively predetermined) firmware, and may access the semiconductor device 1100 by controlling the ECRAM controller 1220. The ECRAM controller 1220 may include a controller interface 1221 processing communication with the semiconductor device 1100. A control instruction for controlling the semiconductor device 1100, data to be written in the memory cell transistors MCT of the semiconductor device 1100, and data to be read from the memory cell transistors MCT of the semiconductor device 1100 may be transmitted via the controller interface 1221. The host interface 1230 may provide a communication function between the data storage system 1000 and an external host. When a control instruction is received from the external host via the host interface 1230, the processor 1210 may control the semiconductor device 1100 in response to the control instruction.

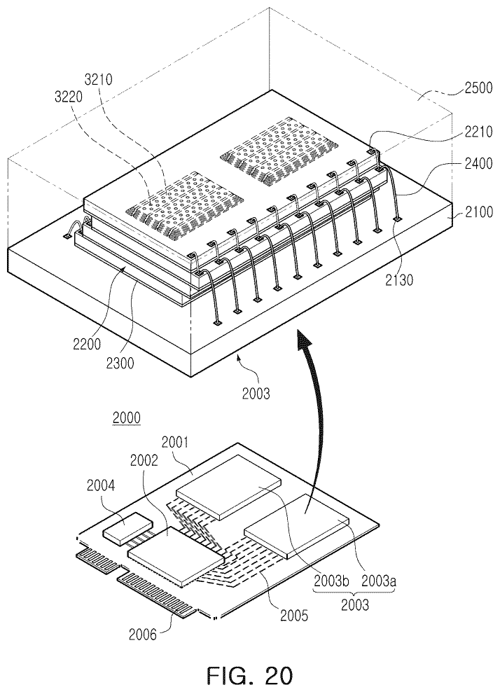

FIG. 20 is a schematic perspective view of a data storage system including a semiconductor device according to some example embodiments.

Referring to FIG. 20, a data storage system 2000 according to some example embodiments of the present disclosure may include a main substrate 2001, a controller 2002 mounted on the main substrate 2001, one or more semiconductor packages 2003, and a DRAM 2004. The semiconductor packages 2003 and the DRAM 2004 may be connected to the controller 2002 via interconnection patterns 2005 formed on the main substrate 2001.

The main substrate 2001 may include a connector 2006 including a plurality of pins coupled to an external host. The number and arrangement of the plurality of pins in the connector 2006 may vary depending on a communication interface between the data storage system 2000 and the external host. In some example embodiments, the data storage system 2000 may communicate with the external host according to one of interfaces such as universal flash storage (UFS), peripheral component interconnect express (PCI-Express), serial advanced technology attachment (SATA), M-Phy for universal serial bus (USB), and the like. However, example embodiments may not be limited thereto. In some example embodiments, the data storage system 2000 may be operated by power supplied from the external host via the connector 2006. The data storage system 2000 may further include a power management integrated circuit (PMIC) distributing, to the controller 2002 and a semiconductor package 2003, power supplied from the external host.

The controller 2002 may write data in the semiconductor package 2003 or read data from the semiconductor package 2003, and may improve operating speed of the data storage system 2000.

The DRAM 2004 may be a buffer memory for alleviating a speed difference between the semiconductor package 2003, a data storage space, and the external host. The DRAM 2004, included in the data storage system 2000, may also operate as a type of cache memory, and may provide a space for temporarily storing data in a control operation on the semiconductor package 2003. When the DRAM 2004 is included in the data storage system 2000, the controller 2002 may further include a DRAM controller for controlling the DRAM 2004 in addition to a NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on lower surfaces of the semiconductor chips 2200, a connection structure 2400 electrically connecting the semiconductor chips 2200 and the package substrate 2100 to each other, and a molding layer 2500 covering the semiconductor chips 2200 and the connection structure 2400 on the package substrate 2100.

The package substrate 2100 may be a printed circuit board including package upper pads 2130. Each semiconductor chip 2200 may include an input/output pad 2210. The input/output pad 2210 may correspond to the input/output pad 1101 of FIG. 24. Each of the semiconductor chips 2200 may include gate stack structures 3210 and channel structures 3220. Each of the semiconductor chips 2200 may include the semiconductor device described above with reference to FIGS. 1 to 17.

In some example embodiments, the connection structure 2400 may be a bonding wire electrically connecting the input/output pad 2210 and the package upper pads 2130 to each other. Accordingly, in each of the first and second semiconductor packages 2003a and 2003b, the semiconductor chips 2200 may be electrically connected to each other using a bonding wire method, and may be electrically connected to the package upper pads 2130 of the package substrate 2100. In some example embodiments, in each of the first and second semiconductor packages 2003a and 2003b, the semiconductor chips 2200 may be electrically connected to each other by a connection structure including a through-silicon via (TSV) instead of the connection structure 2400 using the bonding wire method.

In some example embodiments, the controller 2002 and the semiconductor chips 2200 may be included in one package. In some example embodiments, the controller 2002 and the semiconductor chips 2200 may be mounted on an interposer substrate (lowermost 2200), different from the main substrate 2001, and the controller 2002 and the semiconductor chips may be connected to each other by an interconnection formed on the interposer substrate (lowermost 2200).

According to some example embodiments, as ions are desorbed or acquired, a threshold voltage of a memory cell may change and thus a semiconductor device may store or read data, such that the semiconductor device may operate with a low gate voltage.

In this case, a plurality of diffusion barrier layers may be formed to reduce and/or prevent data loss due to re-diffusion of ions, thereby (significantly) limiting and/or preventing ion diffusion between the diffusion barrier layers. Accordingly, a memory device may have improved retention characteristics without significant data loss.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While some example embodiments have been shown and described above, it will be apparent to those skilled in the art that modifications and variations could be made without departing from the scope of the present disclosure as defined by the appended claims.

What is claimed is:

1. A semiconductor device comprising:
a substrate;
a stack structure including gate electrodes spaced apart from each other in a vertical direction, the vertical direction being perpendicular to an upper surface of the substrate; and
a channel structure extending vertically in a channel hole through the stack structure in the vertical direction,
wherein the channel structure includes
a channel layer on a sidewall of the channel hole,
a resistance switching layer between the sidewall of the channel hole and the channel layer, the resistance switching layer configured to vary an electrical conductivity based on an electrochemical reaction involving a loss or a gain of oxygen ions,
a diffusion barrier structure between the sidewall of the channel hole and the resistance switching layer,
an electrolyte layer between the sidewall of the channel hole and the diffusion barrier structure, and
an ion storage layer between the sidewall of the channel hole and the electrolyte layer, and
the diffusion barrier structure includes at least two diffusion barrier layers sequentially stacked in a direction from the resistance switching layer toward the electrolyte layer.

2. The semiconductor device of claim 1, wherein the diffusion barrier structure has a set thickness and a set ion diffusion coefficient of each of the at least two diffusion barrier layers, and is configured to reduce re-diffusion of the oxygen ions from the ion storage layer.

3. The semiconductor device of claim 2, wherein the at least two diffusion barrier layers have a same thickness.

4. The semiconductor device of claim 3, wherein the ion diffusion coefficient of each of the at least two diffusion barrier layers are different from each other.

5. The semiconductor device of claim 3, wherein
the at least two diffusion barrier layers each respectively include a metal oxide,
the at least two diffusion barrier layers include a same metal material, and
the at least two diffusion barrier layers include different concentrations of oxygen.

6. The semiconductor device of claim 2, wherein
the at least two diffusion barrier layers include a same ion diffusion coefficient, and
a thickness of each of the at least two diffusion barrier layers are different.

7. The semiconductor device of claim 6, wherein the thickness of each of the at least two diffusion barrier layers increases from the electrolyte layer to the resistance switching layer.

8. The semiconductor device of claim 2, wherein the at least two diffusion barrier layers have different ion diffusion coefficients, and have different thicknesses.

9. The semiconductor device of claim 2, wherein the at least two diffusion barrier layers have a same ion diffusion coefficient, and have a same thickness.

10. The semiconductor device of claim 1, wherein a thickness of the diffusion barrier structure is less than a thickness of the channel layer.

11. The semiconductor device of claim 1, wherein
the channel structure further includes
an insulating pillar in a center of the channel hole,
a first tunneling layer between the stack structure and the ion storage layer, and
a second tunneling layer between the diffusion barrier structure and the resistance switching layer.

12. The semiconductor device of claim 1, wherein
the channel layer includes silicon,
the resistance switching layer includes tungsten oxide,
the diffusion barrier structure includes hafnium oxide,
the electrolyte layer includes tantalum oxide, and
the ion storage layer includes tungsten oxide.

13. The semiconductor device of claim 12, wherein an oxygen concentration of the resistance switching layer is less than an oxygen concentration of the ion storage layer.

14. A semiconductor device comprising:
a substrate;
a stack structure including gate electrodes spaced apart from each other in a vertical direction, the vertical direction being perpendicular to an upper surface of the substrate; and
a channel structure extending vertically in a channel hole through the stack structure in the vertical direction,
wherein the channel structure includes
a circular insulating pillar in a center of the channel hole,
an ion-providing structure surrounding an external surface of the circular insulating pillar, the ion-providing structure including a first metal oxide, and the ion-providing structure configured to vary an electrical conductivity based on an electrochemical reaction involving a loss or a gain of oxygen ions,
a diffusion barrier structure surrounding an external surface of the ion-providing structure, the diffusion barrier structure including a second metal oxide,
an electrolyte layer surrounding an external surface of the diffusion barrier structure, the electrolyte layer including a third metal oxide, and
an ion storage layer surrounding an external surface of the electrolyte layer, the ion storage layer including a fourth metal oxide, and
the diffusion barrier structure includes at least two diffusion barrier layers sequentially stacked between the ion-providing structure and the electrolyte layer, the diffusion barrier structure configured to reduce re-diffusion of the oxygen ions from the ion storage layer.

15. The semiconductor device of claim 14, wherein a thickness of the diffusion barrier structure is less than a thickness of the electrolyte layer.

16. The semiconductor device of claim 15, wherein the at least two diffusion barrier layers of the diffusion barrier structure have a same thickness, and have different ion diffusion coefficients.

17. The semiconductor device of claim 15, wherein the at least two diffusion barrier layers of the diffusion barrier structure include a same metal material, and include different concentrations of oxygen.

18. The semiconductor device of claim 15, wherein
the ion-providing structure includes tungsten oxide,
the diffusion barrier structure includes hafnium oxide,
the electrolyte layer includes tantalum oxide, and
the ion storage layer includes tungsten oxide.

19. A data storage system comprising:
a semiconductor storage device including a channel structure in a channel hole extending through gate electrodes stacked on a substrate; and
a controller electrically connected to the semiconductor storage device, the controller configured to control the semiconductor storage device,
wherein the channel structure includes
a circular insulating pillar in a center of the channel hole,
an ion-providing structure surrounding an external surface of the circular insulating pillar, the ion-providing structure including a first metal oxide, and configured to vary an electrical conductivity based on an electrochemical reaction involving a loss or a gain of oxygen ions,
a diffusion barrier structure surrounding an external surface of the ion-providing structure, the diffusion barrier structure including a second metal oxide,
an electrolyte layer surrounding an external surface of the diffusion barrier structure, the electrolyte layer including a third metal oxide, and
an ion storage layer surrounding an external surface of the electrolyte layer, the ion storage layer including a fourth metal oxide,
the diffusion barrier structure includes at least two diffusion barrier layers sequentially stacked between the ion-providing structure and the electrolyte layer, the diffusion barrier structure configured to reduce re-diffusion of the oxygen ions from the ion storage layer.

20. The data storage system of claim 19, wherein
the ion-providing structure includes
a channel layer surrounding the circular insulating pillar, the channel layer including silicon, and
a resistance switching layer surrounding an external surface of the channel layer, the resistance switching layer including the first metal oxide,
the oxygen ions of the resistance switching layer are configured to be lost or gained in response to a voltage of each of the gate electrodes.
